(19) United States
(12) Patent Application Publication
(10) Pub. No.: US 2024/0109217 A1
(43) Pub. Date: Apr. 4, 2024

(54) CUTTING APPARATUS AND CUTTING METHOD

(71) Applicant: DISCO CORPORATION, Tokyo (JP)

(72) Inventor: Tsutomu SUMA, Tokyo (JP)

(21) Appl. No.: 18/470,857

(22) Filed: Sep. 20, 2023

(30) Foreign Application Priority Data
Sep. 29, 2022 (JP) 2022-156586

(51) Int. Cl. B26D 7/08; B26D 1/14; H01L 21/67

(52) U.S. Cl. CPC B26D 7/088; B26D 1/141; H01L 21/67092

(57) ABSTRACT

A cutting liquid supply unit of a cutting apparatus includes a pair of gutter forming nozzles that are disposed to face each other in such a manner as to sandwich a cutting blade and that supply a cutting liquid to the cutting blade to form gutters extending in a processing progression direction, and a tip nozzle that supplies the cutting liquid from the outer circumferential side of the cutting blade toward the cutting blade on the upstream side in the processing progression direction. The tip nozzle supplies the cutting liquid toward a processing point at which the cutting blade cuts into a workpiece, and guides the cutting liquid by the gutters toward the downstream side in the processing progression direction.

### BACKGROUND OF THE INVENTION

### Field of the Invention

The present invention relates to a cutting apparatus and a cutting method.

### Description of the Related Art

For example, in the case where a solid-state imaging element device wafer is cut by a cutting apparatus, a device defect is caused if foreign matter adheres to a device. Therefore, it is important to avoid adhesion of cutting dust generated in the cutting. Thus, there has been provided a cutting apparatus in which a contamination removing component disposed to face a cutting blade in the rotation direction of the cutting blade relative to a processing point is installed on a blade cover that covers the outer circumference of the cutting blade (for example, refer to Japanese Patent Laid-open No. 2006-289509).

### SUMMARY OF THE INVENTION

In recent years, a bonding method for bonding electrodes on device surfaces to each other, which is called hybrid bonding, has begun to be employed. In the hybrid bonding, surfaces are bonded together, and thus, a bonding defect is caused if foreign matter adheres to a device surface. Therefore, it is required that foreign matter is not present on a surface of the cut device wafer.

After the surface of the device wafer has been once dried, it is impossible to remove foreign matter such as cutting dust that has adhered to the surface in the cutting, even when the surface is cleaned later. Thus, it is desired to prevent adhesion of foreign matter in cutting as much as possible.

However, it is difficult to eliminate adhesion of cutting dust to a workpiece even with the cutting apparatus disclosed in Japanese Patent Laid-open No. 2006-289509, and improvement is desired.

Thus, an object of present invention is to provide a cutting apparatus and a cutting method that can suppress adhesion of cutting dust to a workpiece.

In accordance with an aspect of the present invention, there is provided a cutting apparatus including a holding table that holds a workpiece, a cutting unit having a spindle on which a cutting blade that cuts the workpiece held on the holding table is mounted, and a cutting liquid supply unit that supplies a cutting liquid to the cutting blade. The cutting liquid supply unit includes a pair of gutter forming nozzles that are disposed to face each other in such a manner as to sandwich the cutting blade and that supply the cutting liquid to a front surface and a back surface of the cutting blade to form gutters extending in a processing feed direction, and a tip nozzle that supplies the cutting liquid from the outer circumferential side of the cutting blade toward the cutting blade on the upstream side in the processing feed direction. The tip nozzle supplies the cutting liquid toward a processing point at which the cutting blade cuts into the workpiece, and guides the cutting liquid by the gutters to the outside of the workpiece on the downstream side in the processing feed direction.

Preferably, an angle of the cutting liquid supplied from the gutter forming nozzles is equal to or larger than 45 degrees but is equal to or smaller than 85 degrees in a downward direction with respect to a horizontal direction.

Preferably, a flow rate of the cutting liquid supplied from the gutter forming nozzles is equal to or higher than 2.0 L/min but is equal to or lower than 3.0 L/min.

In accordance with another aspect of the present invention, there is provided a cutting method for cutting a workpiece. The cutting method includes a holding step of holding the workpiece on a holding table, and a gutter forming step of forming gutters extending in a processing feed direction, by supplying a cutting liquid from gutter forming nozzles to a front surface and a back surface of a rotating cutting blade, the gutter forming nozzles being disposed to face each other in such a manner as to sandwich the cutting blade. The cutting method also includes a cutting step of, after the gutter forming step is executed, cutting the workpiece held on the holding table by the cutting blade while supplying the cutting liquid from a tip nozzle such that the cutting liquid flows from the outer circumferential side of the cutting blade toward the cutting blade on the upstream side in the processing feed direction, and guiding the cutting liquid including cutting dust by the gutters to the outside of the workpiece on the downstream side in the processing feed direction.

The present invention provides an effect of suppressing adhesion of the cutting dust to the workpiece.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view illustrating an example of the configuration of a cutting apparatus according to an embodiment;

FIG. 2 is a perspective view schematically illustrating a workpiece to be processed by the cutting apparatus illustrated in FIG. 1;

FIG. 3 is a side view schematically illustrating the configuration of a cutting liquid supply unit of the cutting apparatus illustrated in FIG. 2;

FIG. 4 is a front view of the cutting liquid supply unit partly in a cross section along a line IV-IV in FIG. 3;

FIG. 5 is a flowchart illustrating the flow of a cutting method according to the embodiment;

FIG. 6 is a side view schematically illustrating the configuration of a cutting liquid supply unit of a cutting apparatus according to a modification example of the embodiment;

FIG. 7 is a front view of the cutting liquid supply unit partly in a cross section along a line VII-VII in FIG. 6;

FIG. 8 is a plan view illustrating a state of cutting dust adhering to a front surface of a workpiece that has been cut by the cutting apparatus as a product of the present invention; and

FIG. 9 is a plan view illustrating a state of cutting dust adhering to a front surface of a workpiece that has been cut by a cutting apparatus according to a comparative example.

### DETAILED DESCRIPTION OF THE PREFERRED EMBODIMENT

An embodiment of the present invention will be described in detail below with reference to the drawings. The present invention is not limited to the details of the embodiment described below. Further, constituent elements described below cover those which could easily be envisaged by those skilled in the art, and those which are substantially the same as those described below. In addition, configurations described below can be combined as appropriate. Moreover, various omissions, replacements, or changes of the configurations can be made without departing from the gist of the present invention.

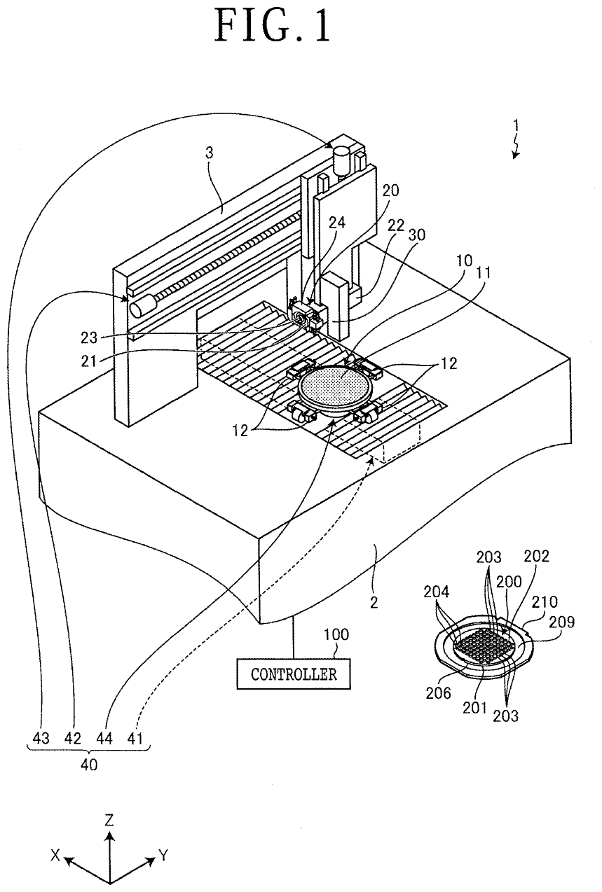

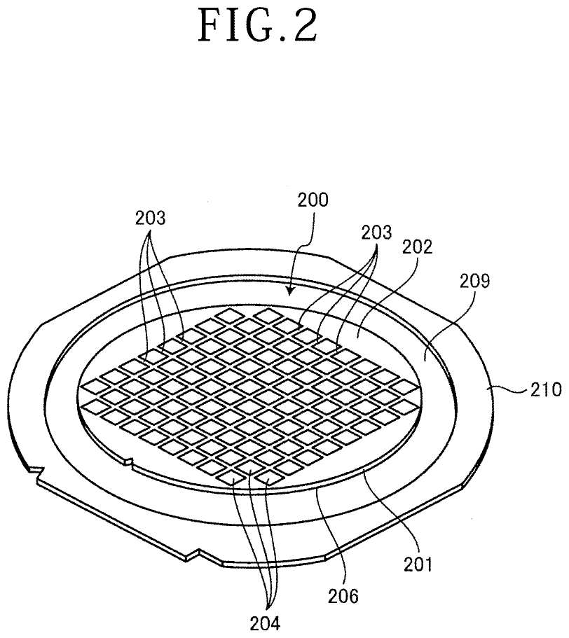

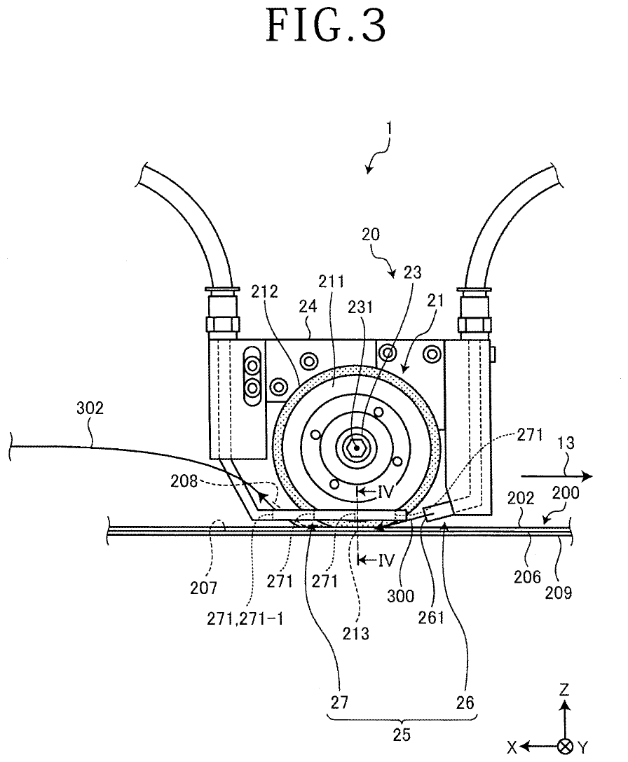

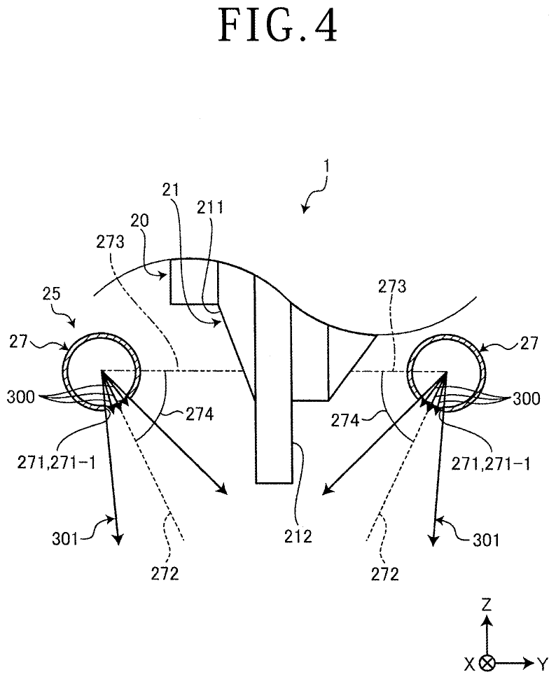

A cutting apparatus according to the embodiment of the present invention will be described on the basis of the drawings. FIG. 1 is a perspective view illustrating an example of the configuration of the cutting apparatus according to the embodiment. FIG. 2 is a perspective view schematically illustrating a workpiece to be processed by the cutting apparatus illustrated in FIG. 1. FIG. 3 is a side view schematically illustrating the configuration of a cutting liquid supply unit of the cutting apparatus illustrated in FIG. 2. FIG. 4 is a front view of the cutting liquid supply unit partly in a cross section along a line IV-IV in FIG. 3.

A cutting apparatus 1 according to the embodiment illustrated in FIG. 1 is a processing apparatus that executes cutting processing of a workpiece 200. The workpiece 200 to be processed by the cutting apparatus 1 illustrated in FIG. 1 is a wafer such as a circular plate-shaped semiconductor wafer or optical device wafer having silicon, sapphire, gallium, or the like as a substrate 201. In the workpiece 200, as illustrated in FIG. 1 and FIG. 2, a plurality of planned dividing lines 203 that intersect each other are set on a front surface 202 of the workpiece 200, and devices 204 are formed in respective regions marked out by the planned dividing lines 203. For example, the devices 204 are integrated circuits (ICs), large scale integration (LSI) circuits, charge coupled device (CCD) image sensors, complementary metal oxide semiconductor (CMOS) image sensors, or various memories (semiconductor storing devices).

In the embodiment, as illustrated in FIG. 1 and FIG. 2, an adhesive tape 209 that has a circular plate shape with a diameter larger than the outer diameter of the workpiece 200 and has an outer edge portion to which an annular frame 210 is stuck is stuck to a back surface 206 of the workpiece 200, which is opposite to the front surface 202, such that the workpiece 200 is placed in an opening of the annular frame 210. The workpiece 200 placed in the opening is thus supported on the annular frame 210. The workpiece 200 is then cut along the planned dividing lines 203 and divided into the individual devices 204.

In the embodiment, the devices 204 are ICs, LSI circuits, or memories (semiconductor storing devices). On the devices 204 of the workpiece 200, devices of another workpiece are placed, and an electrode of each device 204 is bonded to an electrode of the corresponding device of the other workpiece. As described above, in the embodiment, the workpiece 200 to be processed is a wafer for which what is called hybrid bonding is executed. In the present invention, however, the workpiece 200 is not limited to the wafer for which the hybrid bonding is executed.

The cutting apparatus 1 illustrated in FIG. 1 is a processing apparatus that holds the workpiece 200 on a holding table 10 and that executes cutting processing for the workpiece 200 along the planned dividing lines 203 by a cutting blade 21 to divide the workpiece 200 into the individual devices 204.

As illustrated in FIG. 1, the cutting apparatus 1 includes the holding table 10 that holds the workpiece 200 under suction on a holding surface 11 thereof, a cutting unit 20 that cuts the workpiece 200 held on the holding table 10, an image capturing unit 30 that captures an image of the workpiece 200 held on the holding table 10, and a controller 100.

Further, the cutting apparatus 1 includes a moving unit 40 that relatively moves the holding table 10 and the cutting unit 20. The moving unit 40 includes at least a processing feed unit 41 that executes processing feed of the holding table 10 in an X-axis direction parallel to the horizontal direction, an indexing feed unit 42 that executes indexing feed of the cutting unit 20 in a Y-axis direction parallel to the horizontal direction and orthogonal to the X-axis direction, a cutting-in feed unit 43 that executes cutting-in feed of the cutting unit 20 in a Z-axis direction orthogonal to both the X-axis direction and the Y-axis direction and parallel to the vertical direction, and a rotation moving unit 44 that rotates the holding table 10 around the axial center parallel to the Z-axis direction. That is, the moving unit 40 relatively moves the holding table 10 and the cutting unit 20 in the X-axis direction, the Y-axis direction, and the Z-axis direction and around the axial center.

The processing feed unit 41 relatively moves the cutting unit 20 and the holding table 10 along the X-axis direction, which is a processing feed direction, by moving the holding table 10 and the rotation moving unit 44 in the X-axis direction. The indexing feed unit 42 relatively moves the cutting unit 20 and the holding table 10 along the Y-axis direction, which is an indexing feed direction, by moving the cutting unit 20 in the Y-axis direction. The cutting-in feed unit 43 relatively moves the cutting unit 20 and the holding table 10 along the Z-axis direction, which is a cutting-in feed direction, by moving the cutting unit 20 in the Z-axis direction. The rotation moving unit 44 is supported by the processing feed unit 41. The rotation moving unit 44 supports the holding table 10 and is movable in the X-axis direction together with the holding table 10.

Each of the processing feed unit 41, the indexing feed unit 42, and the cutting-in feed unit 43 includes a well-known ball screw disposed rotatably around the axial center, a well-known motor that rotates the ball screw around the axial center, and well-known guide rails that support the holding table 10 or the cutting unit 20 movably in the X-axis direction, the Y-axis direction, or the Z-axis direction. Further, the rotation moving unit 44 includes a motor that rotates the holding table 10 around the axial center.

The holding table 10 has a circular disc shape, and the holding surface 11 for holding the workpiece 200 thereon is formed of a porous ceramic or the like. Moreover, the holding table 10 is disposed to be movable by the processing feed unit 41 between a processing region below the cutting unit 20 and a carrying-in/out region which is separate from the processing region and which the workpiece 200 is carried in and out. Thus, the holding table 10 is movably in the X-axis direction. The holding table 10 is disposed to be rotatable by the rotation moving unit 44 around the axial center parallel to the Z-axis direction.

The holding surface 11 is connected to a suction source which is not illustrated, and suction force is applied to the holding surface 11 from the suction source. Thus, the holding table 10 holds under suction the workpiece 200 placed on the holding surface 11. In the embodiment, the holding table 10 holds the workpiece 200 under suction from the back surface 206 with the interposition of the adhesive tape 209. Further, as illustrated in FIG. 1, a plurality of clamp parts 12 that clamp the annular frame 210 are disposed around the holding table 10.

The cutting unit 20 is a processing unit that has the cutting blade 21 mounted on a spindle 23 and that cuts the workpiece 200 held on the holding table 10. The cutting unit 20 is movable by the indexing feed unit 42 in the Y-axis direction relative to the workpiece 200 held on the holding table 10, and is also movable in the Z-axis direction by the cutting-in feed unit 43.

The cutting unit 20 is attached to a support frame 3 erected from an apparatus main body 2, by the indexing feed unit 42, the cutting-in feed unit 43, and so forth. The cutting unit 20 can position the cutting blade 21 to any position on the holding surface 11 of the holding table 10 by the indexing feed unit 42 and the cutting-in feed unit 43. Moreover, the cutting blade 21 of the cutting unit 20 cuts the workpiece 200 held on the holding table 10 movable in the X-axis direction by the processing feed unit 41.

Thus, when the cutting blade 21 cuts the workpiece 200, the cutting unit 20 moves in a processing progression direction 13 (illustrated in FIG. 3) parallel to the X-axis direction relative to the workpiece 200 held on the holding table 10. The processing progression direction 13 corresponds to the processing feed direction when the cutting blade 21 cuts the workpiece 200.

As illustrated in FIG. 1, the cutting unit 20 has the cutting blade 21, a spindle housing 22 disposed to be movable in the Y-axis direction and the Z-axis direction by the indexing feed unit 42 and the cutting-in feed unit 43, the spindle 23 that is disposed in the spindle housing 22 rotatably around the axial center and that has a tip on which the cutting blade 21 is mounted, and an unillustrated spindle motor that rotates the spindle 23 around the axial center. Further, the cutting unit 20 has a blade cover 24 mounted on a tip surface of the spindle housing 22 as illustrated in FIG. 1 and FIG. 3.

The cutting blade 21 is an extremely thin cutting abrasive stone having a substantially ring shape. The cutting blade 21 is fixed to the tip of the spindle 23. In the embodiment, as illustrated in FIG. 3, the cutting blade 21 is what is called a hub blade that includes a circular base 211 with a circular annular shape and a circular annular cutting edge 212 disposed at the outer circumferential edge of the circular base 211 and configured to cut the workpiece 200. The cutting edge 212 includes abrasive grains of diamond, cubic boron nitride (CBN), or the like and a bond material (binding material) of metal, resin, or the like, and is formed into a predetermined thickness. In the present invention, the cutting blade 21 may be what is called a washer blade having only the cutting edge 212.

The cutting blade 21 is mounted on the tip of the spindle 23 and cuts the workpiece 200 held on the holding surface 11 of the holding table 10. Moreover, a point, on the lower side in the Z-axis direction, of the cutting edge 212 of the cutting blade 21 rotating around an axial center 231 of the spindle 23 and the cutting blade 21 as the rotation center when the cutting blade 21 cuts the workpiece 200 held on the holding table 10 will hereinafter be referred to as a processing point 213 at which the cutting blade 21 cuts into the workpiece 200.

The spindle 23 has the tip on which the cutting blade 21 is mounted, and rotates the cutting blade 21 by rotating around the axial center by the spindle motor. The spindle motor includes a rotor that is disposed on the spindle 23 and that rotates integrally with the spindle 23, and a stator that is disposed on the outer circumferential side of the rotor and in the spindle housing 22 and that rotates the rotor by being supplied with power from a power supply. The spindle motor rotates the spindle 23 around the axial center 231 through rotation of the rotor by the stator.

The blade cover 24 covers at least an upper portion of the cutting blade 21. The blade cover 24 is fixed to the tip surface of the spindle housing 22.

Further, as illustrated in FIG. 3, the cutting apparatus 1 includes a cutting liquid supply unit 25 that supplies a cutting liquid 300 to the cutting blade 21. The cutting liquid supply unit 25 supplies the cutting liquid 300 to the cutting blade 21 when the workpiece 200 held on the holding surface 11 of the holding table 10 is cut by the cutting blade 21. The cutting liquid supply unit 25 has a tip nozzle 26 and a pair of gutter forming nozzles 27.

The nozzles 26 and 27 are attached to the blade cover 24. The nozzles 26 and 27 supply the cutting liquid 300 supplied from a cutting liquid supply source, which is not illustrated, to the cutting blade 21. The tip nozzle 26 is disposed on the upstream side in the processing progression direction 13 relative to the processing point 213 of the cutting edge 212 of the cutting blade 21, and includes a jet port 261 that faces the processing point 213 of the cutting edge 212 of the cutting blade 21 in the X-axis direction. In the cutting of the workpiece 200, the tip nozzle 26 supplies the cutting liquid 300 from the jet port 261 on the upstream side in the processing progression direction 13 such that the cutting liquid 300 flows from the outer circumferential side of the cutting edge 212 of the cutting blade 21 to the processing point 213 of the cutting edge 212 of the cutting blade 21.

The gutter forming nozzles 27 are formed into circular cylindrical pipes that extend in parallel to the X-axis direction, and are disposed at an interval from each other in the Y-axis direction. The lower end of the cutting edge 212 of the cutting blade 21 is positioned between the gutter forming nozzles 27. That is, the gutter forming nozzles 27 are disposed to face each other in the Y-axis direction in such a manner as to sandwich a lower end portion of the cutting edge 212 of the cutting blade 21. Each of the gutter forming nozzles 27 includes jet ports 271 that penetrate an outer wall of the gutter forming nozzle 27 facing the lower end of the cutting edge 212 of the cutting blade 21. In the cutting of the workpiece 200, the gutter forming nozzles 27 supply the cutting liquid 300 from the jet ports 271 to a front surface and a back surface of the lower end of the cutting edge 212 of the cutting blade 21.

In the embodiment, in each of the gutter forming nozzles 27, a plurality of jet ports 271 formed into a slit shape extending in the Z-axis direction are disposed at intervals in the longitudinal direction of the gutter forming nozzle 27. In the embodiment, when each of the gutter forming nozzles 27 is viewed from the Y-axis direction, the plurality of jet ports 271 facing the lower end of the cutting edge 212 of the cutting blade 21 in the Y-axis direction are made, and the jet port 271 (hereinafter, denoted by a reference sign 271-1) is also made on the rear side in the processing progression direction 13 relative to the cutting edge 212 of the cutting blade 21.

As illustrated in FIG. 4, the jet ports 271 and 271-1 of each of the gutter forming nozzles 27 are formed in such a manner that an angle 274 formed by a line segment 272 (illustrated by a dashed line in FIG. 4) that links the center of the gutter forming nozzle 27 and the center of the jet port 271 or 271-1 in the circumferential direction of the gutter forming nozzle 27 and a line segment 273 (illustrated by a two-dot-dash line in FIG. 4) that extends in the horizontal direction along the Y-axis direction from the center of the gutter forming nozzle 27 to the cutting edge 212 of the cutting blade 21 becomes at least 45 degrees but at most 85 degrees. When the angle 274 formed by the line segment 272 and the line segment 273 is at least 45 degrees but at most 85 degrees as described above, the angle (or orientation) 274 of the jet ports 271 and 271-1 is also at least 45 degrees but at most 85 degrees in the downward direction with respect to the horizontal direction. The angle 274 of the jet ports 271 and 271-1 is also the angle (orientation) 274 of the cutting liquid 300 supplied from the jet ports 271 and 271-1 of the gutter forming nozzle 27 to the cutting edge 212 of the cutting blade 21 and is the angle with respect to the horizontal direction.

Thus, the angle 274 of the cutting liquid 300 supplied from the jet ports 271 and 271-1 of the gutter forming nozzle 27 to the cutting edge 212 of the cutting blade 21 is at least 45 degrees but at most 85 degrees in the downward direction with respect to the horizontal direction. With the configuration in which the angle 274 of the cutting liquid 300 supplied to the cutting edge 212 of the cutting blade 21 is at least 45 degrees but at most 85 degrees in the downward direction with respect to the horizontal direction, the gutter forming nozzles 27 can suppress direct collision of the cutting liquid 300 supplied from the jet ports 271 and 271-1 with the cutting liquid 300 jetted from the jet port 261 of the tip nozzle 26, and also suppress collision thereof with the cutting liquid 300 that has been supplied from the jet ports 271 and 271-1 and reflected at the workpiece 200.

Moreover, in the embodiment, the cutting liquid supply unit 25 supplies the cutting liquid 300 from the cutting liquid supply source to the gutter forming nozzles 27 in such a manner that the flow rate of the cutting liquid 300 supplied from the pair of gutter forming nozzles 27 to the cutting blade 21 becomes at least 2.0 L/min but at most 3.0 L/min. That is, in the present invention, it is preferable that, in the cutting liquid supply unit 25, the flow rate of the cutting liquid 300 supplied from the jet port 271 or 271-1 of the gutter forming nozzle 27 be at least 0.5 L/min but at most 0.7 L/min.

As described above, in the cutting liquid supply unit 25 of the cutting apparatus 1 according to the present invention, the flow rate of the cutting liquid 300 supplied to the pair of gutter forming nozzles 27 is higher than that of the cutting liquid 300 supplied to blade nozzles used in the existing techniques. The reason why the cutting liquid supply unit 25 supplies the cutting liquid 300 from the cutting liquid supply source to the pair of gutter forming nozzles 27 in such a manner that the flow rate of the cutting liquid 300 supplied from the pair of gutter forming nozzles 27 to the cutting blade 21 becomes at least 2.0 L/min but at most 3.0 L/min is because it is impossible to form gutters 301 by the cutting liquid 300 when the flow rate of the cutting liquid 300 supplied from the pair of gutter forming nozzles 27 to the cutting blade 21 is lower than 2.0 L/min, and it becomes difficult to cause the cutting liquid 300 supplied from the tip nozzle 26 to pass between the gutters 301 when the flow rate exceeds 3.0 L/min.

Further, in the embodiment, the cutting liquid supply unit 25 supplies the cutting liquid 300 from the cutting liquid supply source to the tip nozzle 26 in such a manner that the flow rate of the cutting liquid 300 supplied from the jet port 261 of the tip nozzle 26 to the cutting blade 21 becomes at least 0.8 L/min but at most 1.5 L/min.

As described above, the gutter forming nozzles 27 supply the cutting liquid 300 at the above-described flow rate and set the angle 274 of the cutting liquid 300 supplied to the cutting edge 212 of the cutting blade 21 to at least 45 degrees but at most 85 degrees in the downward direction with respect to the horizontal direction, to thereby suppress direct collision of the cutting liquid 300 supplied from the jet ports 271 and 271-1 with the cutting liquid 300 supplied from the jet port 261 of the tip nozzle 26 and also suppress collision thereof with the cutting liquid 300 that has been supplied from the jet ports 271 and 271-1 and reflected at the workpiece 200. In addition to this, with the jet ports 271-1 disposed on the rear side in the processing progression direction 13 relative to the cutting edge 212 of the cutting blade 21, the gutter forming nozzles 27 form the gutters 301 by the cutting liquid 300 such that the gutters 301 extend in the processing progression direction 13 and also extend to the rear side in the processing progression direction 13 relative to the cutting blade 21, as illustrated in FIG. 4. The gutters 301 are streams of the cutting liquid 300 supplied from the jet ports 271 and 271-1. In the embodiment, the gutters 301 formed by the cutting liquid 300 supplied from the jet ports 271 and 271-1 of the respective gutter forming nozzles 27 are included in a range of 45 to 85 degrees in the downward direction with respect to the horizontal direction.

As described above, the cutting liquid supply unit 25 of the cutting apparatus 1 according to the embodiment forms the gutters 301 by the cutting liquid 300 supplied from the gutter forming nozzles 27. With this, the cutting liquid 300 supplied from the jet port 261 of the tip nozzle 26 is entrained by the rotating cutting blade 21, and is conveyed along the gutters 301 to be splashed up from the rear side of the cutting blade 21 in the processing progression direction 13 as illustrated by an arrow 302 in FIG. 3 and be scattered toward the outer circumference of the workpiece 200. Accordingly, in the cutting apparatus 1 according to the embodiment, cutting dust 208 generated due to the cutting of the workpiece 200 by the cutting blade 21 is taken in the stream of the cutting liquid 300 supplied from the tip nozzle 26, as illustrated by the arrow 302 in FIG. 3, and the cutting liquid 300 is scattered toward the outer circumference of the workpiece 200.

The reason why it is desirable that the angle 274 of the cutting liquid 300 supplied from the jet ports 271 and 271-1 of each of the gutter forming nozzles 27 to the cutting edge 212 of the cutting blade 21 be at least 45 degrees but at most 85 degrees in the downward direction with respect to the horizontal direction is because it is impossible to form the gutters 301 due to the following reasons. When the angle 274 is smaller than 45 degrees, the cutting liquid 300 supplied from the jet ports 271 and 271-1 of the gutter forming nozzles 27 directly gets contact with the cutting blade 21 and is scattered in all directions in the vicinity of the processing point 213. When the angle 274 exceeds 85 degrees, the cutting liquid 300 supplied from the jet ports 271 and 271-1 of the gutter forming nozzles 27 collides with the cutting liquid 300 reflected at the workpiece 200 and is scattered in all directions in the vicinity of the processing point 213. Further, when the cutting liquid 300 is scattered in all directions in the vicinity of the processing point 213, it becomes difficult for the cutting liquid 300 supplied from the tip nozzle 26 to take therein the cutting dust 208 at the processing point 213 due to the cutting liquid 300 scattered in all directions in the vicinity of the processing point 213. In addition, the cutting liquid 300 supplied from the tip nozzle 26 is not entrained by the rotation of the cutting blade 21 and is scattered in all directions, and it is impossible to suppress adhesion of the cutting dust 208 to the front surface 202 of the workpiece 200 held on the holding table 10. Therefore, it is desirable that the angle 274 of the cutting liquid 300 supplied from the jet ports 271 and 271-1 of each of the gutter forming nozzles 27 to the cutting edge 212 of the cutting blade 21 be at least 45 degrees but at most 85 degrees in the downward direction with respect to the horizontal direction.

The axial center 231 of the cutting blade 21 and the spindle 23 of the cutting unit 20 is set in parallel to the Y-axis direction.

The image capturing unit 30 is fixed to the cutting unit 20 to move integrally with the cutting unit 20. The image capturing unit 30 includes an imaging element that captures an image of a region, to be divided, of the workpiece 200 that is held on the holding table 10 and that is yet to be cut. The imaging element is a CCD imaging element or a CMOS imaging element, for example. The image capturing unit 30 captures an image of the workpiece 200 held on the holding table 10. This image is used for alignment to adjust the positions of the workpiece 200 and the cutting blade 21, for example. The image capturing unit 30 then outputs the captured image to the controller 100.

Moreover, the cutting apparatus 1 includes an X-axis direction position detecting unit, which is not illustrated, for detecting the position of the holding table 10 in the X-axis direction, a Y-axis direction position detecting unit, which is not illustrated, for detecting the position of the cutting unit 20 in the Y-axis direction, and a Z-axis direction position detecting unit, which is not illustrated, for detecting the position of the cutting unit 20 in the Z-axis direction. Each of the X-axis direction position detecting unit and the Y-axis direction position detecting unit can include a linear scale parallel to the X-axis direction or the Y-axis direction and a reading head. The Z-axis direction position detecting unit detects the position of the cutting unit 20 in the Z-axis direction by a pulse of a motor. Each of the X-axis direction position detecting unit, the Y-axis direction position detecting unit, and the Z-axis direction position detecting unit outputs the position of the holding table 10 in the X-axis direction or the position of the lower end of the cutting edge 212 of the cutting unit 20 in the Y-axis direction or the Z-axis direction to the controller 100.

In the embodiment, the positions of the holding table 10 and the cutting unit 20 of the cutting apparatus 1 in the X-axis direction, the Y-axis direction, and the Z-axis direction are defined on the basis of an unillustrated reference position that is defined in advance. In the embodiment, the positions in the X-axis direction, the Y-axis direction, and the Z-axis direction are determined on the basis of the distances in the X-axis direction, the Y-axis direction, and the Z-axis direction from the reference position. In the embodiment, XY-coordinates represented by the X-axis direction and the Y-axis direction of the cutting apparatus 1 (coordinates indicated by the distance in the X-axis direction from the reference position, which indicates the position in the X-axis direction, and the distance in the Y-axis direction from the reference position, which indicates the position in the Y-axis direction) indicate any position in the workpiece 200 held on the holding surface 11 of the holding table 10 in some cases.

The controller 100 controls the respective constituent elements of the cutting apparatus 1 and causes the cutting apparatus 1 to execute processing operation for the workpiece 200. The controller 100 is a computer having a calculation processing device having a microprocessor such as a central processing unit (CPU), a storing device having a memory such as a read only memory (ROM) or random access memory (RAM), and an input-output interface device. The calculation processing device of the controller 100 executes calculation processing according to a computer program stored in the storing device and outputs a control signal for controlling the cutting apparatus 1 to the respective constituent elements of the cutting apparatus 1 through the input-output interface device.

The controller 100 is connected to a display unit, which is not illustrated, including a liquid crystal display device or the like that displays the state of the processing operation, an image, and so forth, and to an input unit, which is not illustrated, used when an operator registers information regarding the contents of processing or the like. The input unit includes a touch panel disposed on the display unit.

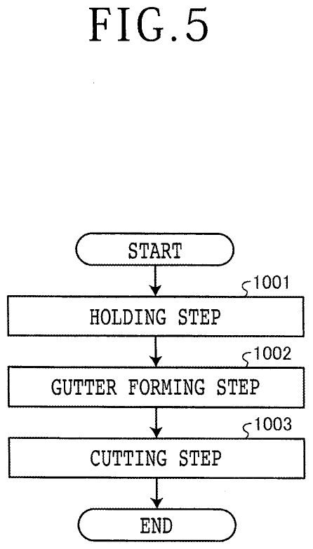

Next, a cutting method according to the embodiment will be described. FIG. 5 is a flowchart illustrating the flow of the cutting method according to the embodiment. The cutting method according to the embodiment is a method for cutting the workpiece 200 by the above-described cutting apparatus 1, and is also the processing operation of the cutting apparatus 1.

In the cutting apparatus 1 with the above-described configuration, processing conditions are set in the controller 100, and the workpiece 200 is placed on the holding surface 11 of the holding table 10. The cutting apparatus 1 starts the processing operation, that is, the cutting method according to the embodiment, when the controller 100 accepts a start instruction of the processing operation from an operator or the like. The cutting method according to the embodiment includes a holding step 1001, a gutter forming step 1002, and a cutting step 1003 as illustrated in FIG. 5.

The holding step 1001 is a step of holding the workpiece 200 on the holding table 10. In the embodiment, in the holding step 1001, the cutting apparatus 1 holds the workpiece 200 under suction on the holding surface 11 with the interposition of the adhesive tape 209, and clamps the annular frame 210 by the clamp parts 12.

The gutter forming step 1002 is a step of supplying the cutting liquid 300 from the gutter forming nozzles 27, which are disposed to face each other in such a manner as to sandwich the cutting blade 21, to the front surface and the back surface of the rotating cutting blade 21, and forming the gutters 301 by the cutting liquid 300 such that the gutters 301 extend in the processing progression direction 13. In the embodiment, in the gutter forming step 1002, in the cutting apparatus 1, the controller 100 causes the spindle 23 to rotate around the axial center and controls the cutting liquid supply unit 25 to supply the cutting liquid 300 from the jet port 261 of the tip nozzle 26 to the cutting edge 212 of the cutting blade 21 and supply the cutting liquid 300 from the jet ports 271 and 271-1 of the gutter forming nozzles 27 to the cutting edge 212 of the cutting blade 21. Further, in the gutter forming step 1002, the cutting apparatus 1 forms the gutters 301 by the cutting liquid 300 such that the gutters 301 extend in the processing progression direction 13 as illustrated in FIG. 4.

The cutting step 1003 is a step of, after the gutter forming step 1002 is executed, cutting the workpiece 200 held on the holding table 10 by the cutting blade 21 while supplying the cutting liquid 300 from the tip nozzle 26 such that the cutting liquid 300 flows from the outer circumferential side of the cutting blade 21 to the cutting blade 21 on the upstream side in the processing progression direction 13, and guiding the cutting liquid 300 including the cutting dust 208 by the gutters 301 toward the outer circumference of the workpiece 200 on the downstream side in the processing progression direction 13. In the embodiment, in the cutting step 1003, in the cutting apparatus 1, the controller 100 controls the moving unit 40 to move the holding table 10 to the lower side of the image capturing unit 30, and causes the image capturing unit 30 to capture an image of the workpiece 200 held under suction on the holding table 10, to thereby perform alignment.

In the embodiment, in the cutting step 1003, in the cutting apparatus 1, the controller 100 controls the moving unit 40 and so forth on the basis of the processing conditions to relatively move the cutting blade 21 and the workpiece 200 along the planned dividing line 203 and causes the cutting blade 21 to cut into the workpiece 200 along the planned dividing line 203 until the cutting blade 21 reaches the adhesive tape 209 while the cutting liquid 300 is supplied from the nozzles 26 and 27 to the cutting blade 21, thereby cutting the workpiece 200. According to the processing conditions, the cutting apparatus 1 cuts the workpiece 200 along the planned dividing lines 203 and forms cut grooves 207 (illustrated in FIG. 3) for splitting the workpiece 200 along the planned dividing lines 203, to divide the workpiece 200 into the individual devices 204.

In the embodiment, in the cutting step 1003, in the cutting apparatus 1, when the cutting blade 21 cuts the workpiece 200 along the planned dividing line 203, the cutting liquid 300 supplied from the jet port 261 of the tip nozzle 26 is entrained by the rotating cutting blade 21 and is conveyed along the gutters 301 to be splashed up from the rear side of the cutting blade 21 in the processing progression direction 13 as illustrated by the arrow 302 in FIG. 3 and be scattered toward the outer circumference of the workpiece 200. Moreover, in the embodiment, in the cutting step 1003, in the cutting apparatus 1, when the cutting blade 21 cuts the workpiece 200 along the planned dividing line 203, the stream of the cutting liquid 300 supplied from the tip nozzle 26 takes therein the cutting dust 208 generated due to the cutting of the workpiece 200 by the cutting blade 21, and is scattered toward the outer circumference of the workpiece 200. In this manner, in the cutting step 1003, the tip nozzle 26 supplies the cutting liquid 300 toward the processing point 213 at which the cutting blade 21 cuts into the workpiece 200, to guide the cutting liquid 300 by the gutters 301 toward the outer circumference of the workpiece 200 on the downstream side in the processing progression direction 13.

In the embodiment, in the cutting step 1003, when the workpiece 200 has been cut along all the planned dividing lines 203, the cutting unit 20 is retracted from the holding table 10, and the holding table 10 is moved from the processing region toward the carrying-in/out region. The cutting apparatus 1 stops the movement of the holding table 10 in the carrying-in/out region, stops the suction holding of the workpiece 200 on the holding table 10, and releases the clamping by the clamp parts 12 to end the processing operation.

In the cutting apparatus 1 and the cutting method according to the embodiment described above, the cutting apparatus 1 includes the cutting liquid supply unit 25 having the pair of gutter forming nozzles 27 and the tip nozzle 26 and forms the gutters 301 by the cutting liquid 300 supplied from the gutter forming nozzles 27. In the cutting apparatus 1 and the cutting method according to the embodiment, the cutting liquid 300 supplied from the tip nozzle 26 toward the processing point 213 in the cutting of the workpiece 200 takes therein the cutting dust 208 generated at the processing point 213 and is conveyed along the gutters 301 to be guided toward the outer circumference of the workpiece 200. Therefore, adhesion of the cutting dust 208 to the front surface 202 of the workpiece 200 can be suppressed.

As a result, the cutting apparatus 1 and the cutting method according to the embodiment provide an effect of suppressing adhesion of the cutting dust 208 to the workpiece 200.

### Modification Example

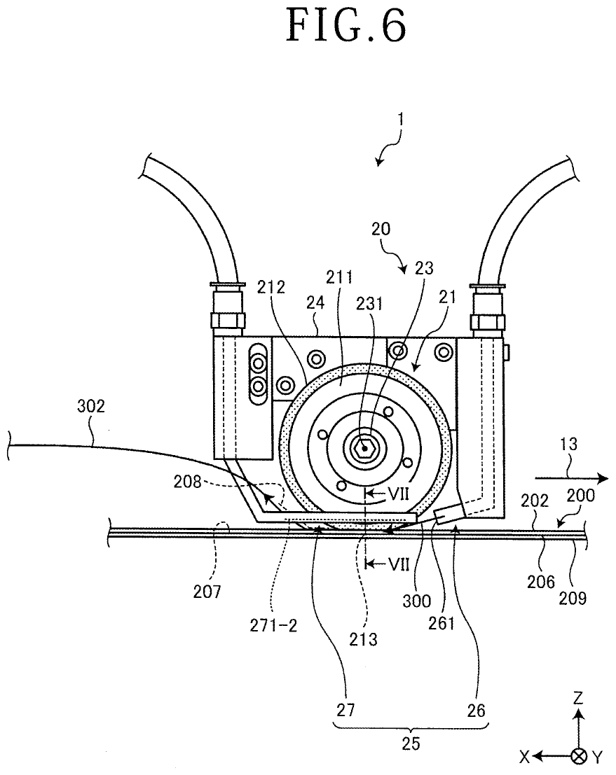

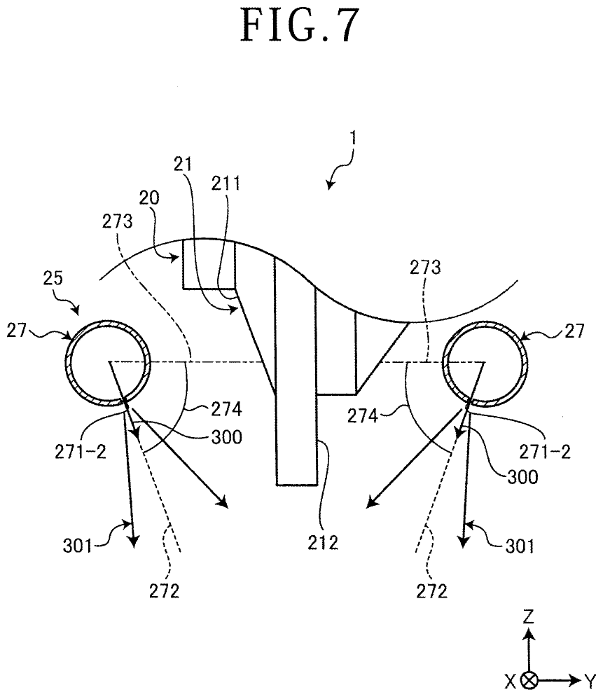

Next, a cutting apparatus according to a modification example of the embodiment will be described on the basis of the drawings. FIG. 6 is a side view schematically illustrating the configuration of a cutting liquid supply unit of the cutting apparatus according to the modification example of the embodiment. FIG. 7 is a front view of the cutting liquid supply unit partly in a cross section along a line VII-VII in FIG. 6. In FIG. 6 and FIG. 7, the same part as that of the embodiment is given the same reference sign, and description thereof is omitted.

The cutting apparatus 1 according to the modification example is the same as that of the embodiment except that jet ports 271-2 of the gutter forming nozzles 27 linearly extend along the processing progression direction 13, that is, the longitudinal direction of the gutter forming nozzles 27, as illustrated in FIG. 6. Further, in the cutting apparatus 1 according to the modification example, the ends of the jet ports 271-2 of the gutter forming nozzles 27 on the rear side in the processing progression direction 13 are located on the rear side in the processing progression direction 13 relative to the cutting blade 21 as illustrated in FIG. 6. Moreover, in the cutting apparatus 1 according to the modification example, as illustrated in FIG. 7, the angle 274 of the jet ports 271-2 of the gutter forming nozzles 27 is at least 45 degrees but at most 85 degrees in the downward direction with respect to the horizontal direction, similarly to the embodiment.

The cutting apparatus 1 according to the modification example forms the gutters 301 by the cutting liquid 300 supplied from the gutter forming nozzles 27. Thus, the cutting liquid 300 supplied from the tip nozzle 26 toward the processing point 213 in the cutting of the workpiece 200 takes therein the cutting dust 208 generated at the processing point 213 and is conveyed along the gutters 301 to be guided toward the outer circumference of the workpiece 200. Therefore, an effect of suppressing adhesion of the cutting dust 208 to the workpiece 200 is provided similarly to the embodiment.

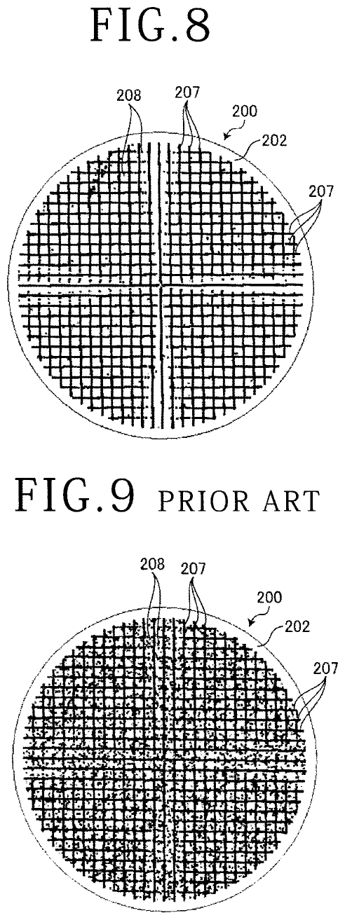

Next, the inventor of the present invention has checked the effects of the cutting apparatus 1 according to the present invention. FIG. 8 is a plan view illustrating a state of cutting dust adhering to a front surface of a workpiece that has been cut by the cutting apparatus as a product of the present invention. FIG. 9 is a plan view illustrating a state of cutting dust adhering to a front surface of a workpiece that has been cut by a cutting apparatus according to a comparative example.

In the check, as the product of the present invention, the number of pieces of cutting dust 208 (illustrated in FIG. 8) that adhered to the front surface 202 of the workpiece 200 when the workpiece 200 was cut by the cutting apparatus 1 according to the embodiment was counted. Further, as the comparative example, the number of pieces of cutting dust 208 (illustrated in FIG. 9) that adhered to the front surface 202 of the workpiece 200 when the workpiece 200 was cut by the cutting apparatus 1 including, instead of the gutter forming nozzles 27, blade nozzles used in the existing techniques and having no jet port 271-1 but the jet ports 271 whose angle 274 was 40 degrees was counted.

In the comparative example illustrated in FIG. 9, the number of pieces of the cutting dust 208 that adhered to the front surface 202 of the workpiece 200 was 5043. In contrast to such a comparative example, in the product of the present invention illustrated in FIG. 8, the number of pieces of the cutting dust 208 that adhered to the front surface 202 of the workpiece 200 was 438. Thus, according to the examples in FIG. 8 and FIG. 9, it has turned out that adhesion of the cutting dust 208 to the workpiece 200 can be suppressed by making the jet ports 271-1 on the rear side in the processing progression direction 13 relative to the cutting blade 21 and setting the angle 274 of the cutting liquid 300 supplied from the jet ports 271 and 271-1 to at least 45 degrees but at most 85 degrees in the downward direction with respect to the horizontal direction.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A cutting apparatus comprising:
a holding table that holds a workpiece;
a cutting unit having a spindle on which a cutting blade that cuts the workpiece held on the holding table is mounted; and
a cutting liquid supply unit that supplies a cutting liquid to the cutting blade, wherein
the cutting liquid supply unit includes
a pair of gutter forming nozzles that are disposed to face each other in such a manner as to sandwich the cutting blade and that supply the cutting liquid to a front surface and a back surface of the cutting blade to form gutters extending in a processing feed direction, and
a tip nozzle that supplies the cutting liquid from an outer circumferential side of the cutting blade toward the cutting blade on an upstream side in the processing feed direction, and
the tip nozzle supplies the cutting liquid toward a processing point at which the cutting blade cuts into the workpiece, and guides the cutting liquid by the gutters to outside of the workpiece on a downstream side in the processing feed direction.

2. The cutting apparatus according to claim 1, wherein
an angle of the cutting liquid supplied from the gutter forming nozzles is equal to or larger than 45 degrees but is equal to or smaller than 85 degrees in a downward direction with respect to a horizontal direction.

3. The cutting apparatus according to claim 1, wherein
a flow rate of the cutting liquid supplied from the gutter forming nozzles is equal to or higher than 2.0 L/min but is equal to or lower than 3.0 L/min.

4. A cutting method for cutting a workpiece, the cutting method comprising:
a holding step of holding the workpiece on a holding table;
a gutter forming step of forming gutters extending in a processing feed direction, by supplying a cutting liquid from gutter forming nozzles to a front surface and a back surface of a rotating cutting blade, the gutter forming nozzles being disposed to face each other in such a manner as to sandwich the cutting blade; and
a cutting step of, after the gutter forming step is executed, cutting the workpiece held on the holding table by the cutting blade while supplying the cutting liquid from a tip nozzle such that the cutting liquid flows from an outer circumferential side of the cutting blade toward the cutting blade on an upstream side in the processing feed direction, and guiding the cutting liquid including cutting dust by the gutters to outside of the workpiece on a downstream side in the processing feed direction.
